(19) United States
(12) Patent Application Publication
(10) Pub. No.: US 2003/0205815 A1
(43) Pub. Date: Nov. 6, 2003

(54) Fabrication method of integrated circuits with borderless vias and low dielectric constant inter-metal dielectrics

(76) Inventor: Henry Chung, Cupertino, CA (US)

Correspondence Address: Roberts & Mercanti, LLP, P.O. Box 484, Princeton, NJ, 08542-0484, US

(21) Appl. No.: 10/405,583

(22) Filed: Apr. 1, 2003

Related U.S. Application Data
(62) Division of application No. 09/328,645, filed on Jun. 9, 1999, now abandoned.

(51) Int. Cl. H01L 23/48; H01L 23/52; H01L 29/40

(52) U.S. Cl. 257/758

(57) ABSTRACT

The invention relates to the formation of structures in microelectronic devices such as integrated circuit devices by means of borderless via architectures in intermetal dielectrics. An integrated circuit structure having a substrate, a layer of a first dielectric material on the substrate; and spaced apart metal contacts on the layer of the first dielectric material. There is a space between adjacent metal contacts and each space is filled with the first dielectric material. A recess is formed in the filled spaces of the first dielectric material which extends from a level at a top of the metal contacts a part of the distance toward the substrate. A second dielectric layer is on at least some of the metal contacts and in the recesses on the filled spaces of the first dielectric material such that there is optionally a gap in the recesses of the second dielectric layer at side walls of the metal contacts. An additional layer of the first dielectric material is on the second dielectric layer. Vias extending through the additional layer of the first dielectric layer and the second dielectric layer extending to the top of at least some of the metal contacts and optionally to the gaps. The first dielectric material and the second dielectric material have substantially different etch resistance properties.

### BACKGROUND OF THE INVENTION

1. Field of the Invention

The present invention relates to the formation of structures in microelectronic devices such as integrated circuit devices. More particularly, the invention relates to the formation of borderless vias in intermetal dielectrics.

2. Description of the Related Art

As feature sizes in the production of integrated circuits are reduced, problems of packing density become increasingly difficult to overcome. The formation of borderless vias is one method to reduce metal pitch in and packing density of integrated circuits. However, it is exceedingly difficult to form borderless vias in conventional subtractive interconnect patterning. The major problem is that deep and narrow trenches are produced at the side of metal lines in via etching whenever vias are misaligned to the underlying metal lines. The trench depth is extremely difficult to control since it is common practice to excess plasma etch in via etch to ensure that via holes are completely open. Organic byproducts are produced in dielectric plasma etching when opening via holes. Those byproducts accumulated at the bottom of trenches cannot be effectively removed by oxygen-based plasma or ashing which are commonly used techniques to strip photoresist used in integrated circuit fabrication. Liquid organic chemicals, which are also commonly used to remove organic byproducts, often cause corrosion of metals from which interconnects are made. As a result, via resistance can be very high and, thus, the performance and reliability of integrated circuits degrade. In extreme cases, integrated circuits fail to function when via holes are totally blocked and vias become electrically open.

The cause of these issues of conventional architectures is the lack of a etchstop or plasma etch selectivity when opening vias. These occur in different ways. Usually the same kind of inorganic dielectric is typically used for the via-level and metal-level inter-level dielectrics (IMD's). Even when two different kinds of inorganic dielectrics are used, as far as plasma etching for via holes is concerned, the difference between these two kinds of inorganic dielectrics is insignificant. As a result, via etch continues even when via holes are already fully opened as long as there is misalignment between via and the underlying interconnects or metal lines. The use of two different kinds of dielectrics, one inorganic and the other organic, have been used for the metal-level and the via-level IMD's, respectively, in some prior architectures. This architecture does not have the aforesaid disadvantage architectures since there is very high plasma etch selectivity between inorganic and organic dielectrics. However, its weakness is associated with the photoresist, which is commonly used for patterning, a key technique in integrated circuit fabrication. In conventional integration methods, both the photoresist and the organic IMD's are exposed at the completion of via etch. The organic via-level dielectric is attacked, resulting in deep trenches along the side of metal lines when removing the photoresist which is also organic.

According to the invention one ensures that the part of the via-level IMD, which is exposed to via etch plasma due to misalignment between via and metal lines, does not etch or only insignificantly etches in via openings and during resist removal following via etch. The invention provides borderless vias in integrated circuits. In the ideal architecture is that the dielectric immediately above the top of metal lines, Level A in FIG. 2A, is different from the via-level IMD or the IMD below Level A in FIG. 2A. In other words, Dielectric I significantly differs from Dielectric II in plasma etch characteristics. For example, if Dielectric I is inorganic, Dielectric II is organic and vice versa. Dielectric, which is used to fill the gap between metal lines, also covers metal lines in integrated circuit fabrication. Therefore, an etchback step is required to remove the dielectric from the top of metal lines before the etchstop layer is deposited.

In practice, Dielectric I is kept below Level B in FIG. 2B to ensure that no Dielectric I on top of metal lines. The spacing between Level A and Level B should be kept as small as possible. As a result, the metal-level IMD consists of two dissimilar dielectrics and the thin dielectric is on the top. It is noted that the demarcation at Level B does not exist in conventional architectures. An objective of the invention objective can be achieved by adding an etchstop layer in between a resist and an organic IMD so that either resist or the organic dielectric can be selectively removed. The etchstop can be a permanent or sacrificial layer. An improvement in process integration is thus to remove the dielectric which fills the gap in between metal lines from the top of metal lines.

### SUMMARY OF THE INVENTION

The invention provides an integrated circuit structure which comprises

(a) a substrate;

(b) a layer of a first dielectric material on the substrate;

(c) a plurality of spaced apart metal contacts on the layer of the first dielectric material;

(d) a space between adjacent metal contacts, each space being filled with the first dielectric material;

(e) a recess in the filled spaces of the first dielectric material extending from a level at a top of the metal contacts a part of the distance toward the substrate;

(f) a second dielectric layer on at least some of the metal contacts and in the recesses on the filled spaces of the first dielectric material such that there is optionally a gap in at least one of the recesses of the second dielectric layer at a side wall of a metal contact;

(g) an additional layer of the first dielectric material on the second dielectric layer;

(h) at least one via extending through the additional layer of the first dielectric layer and the second dielectric layer extending to the top of at least one of the metal contacts and optionally to a gap;

wherein the first dielectric material and the second dielectric material have substantially different etch resistance properties.

The invention also provides an integrated circuit structure which comprises

(a) a substrate;

(b) a layer of a first dielectric material on the substrate;

(c) a plurality of spaced apart metal contacts on the layer of the first dielectric material;

(d) a space between adjacent metal contacts, each space being filled with a second

dielectric material;

(e) a recess in the filled spaces of the second dielectric material extending from a level at a top of the metal contacts a part of the distance toward the substrate;

(f) an additional layer of the first dielectric layer on at least some of the metal contacts and in the recesses on the filled spaces of the second dielectric material such that there is optionally a gap in at least one the recesses of the first dielectric layer at a side wall of a metal contact;

(g) at least one via extending through the additional layer of the first dielectric layer extending to the top of at least one of the metal contacts and optionally to a gaps;

wherein the first dielectric material and the second dielectric material have substantially different etch resistance properties.

The invention further provides a process for producing an integrated circuit structure which comprises

(a) providing a substrate;

(b) depositing a layer of a first dielectric material onto the substrate;

(c) forming a pattern of metal contacts on the layer of the first dielectric material including a space between adjacent metal contacts;

(d) depositing a layer of the first dielectric material on a top surface of the metal contacts and filling in the space between the metal contacts with the first dielectric material;

(e) removing the first dielectric material from the top surface of the metal contacts and removing an upper portion of the first dielectric material from the filled space between the metal contacts to form a recess;

(f) depositing a layer of a second dielectric material on the metal contacts and filling the recess with second dielectric material, wherein the first dielectric material and the second dielectric material have substantially different etch resistance properties;

(g) depositing an additional layer of the first dielectric material over the layer of the second dielectric material;

(h) depositing a layer of a photoresist on the additional layer of the first dielectric material;

(i) imagewise removing a portion of the photoresist over some of the metal contacts and optionally over a portion of at least one of the filled recesses adjacent to a side wall of a metal contact;

(j) removing the portion of the layer of the additional layer of the first dielectric material under the removed portion of the photoresist;

(k) removing the balance of the photoresist layer, and removing the portion of the second dielectric material under the removed portion of the additional layer of the first dielectric material until reaching at least one of the metal contacts and optionally reaching the space filled by the first dielectric material thus forming at least one via through the additional layer of the first dielectric material and through the layer of the second dielectric material.

The invention still further provides a process for producing an integrated circuit structure which comprises

(a) providing a substrate;

(b) depositing a layer of a first dielectric material onto the substrate;

(c) forming a pattern of metal contacts on the layer of the first dielectric material including a space between adjacent metal contacts;

(d) depositing a layer of a second dielectric material on a top surface of the metal contacts and filling in the space between the metal contacts with the, second dielectric material;

(e) removing the second dielectric material from the top surface of the metal contacts and removing an upper portion of the second dielectric material from the filled space between the metal contacts to form a recess;

(f) depositing an additional layer of a first dielectric material on the metal contacts and filling the recess with first dielectric material, wherein the first dielectric material and the second dielectric material have substantially different etch resistance properties;

(g) depositing a layer of a sacrificial metal on the additional layer of the first dielectric material;

(h) depositing a layer of a photoresist on the layer of the sacrificial metal layer;

(k) imagewise removing a portion of the photoresist over some of the metal contacts and optionally over a portion of at least one of the filled recesses adjacent to a side wall of a metal contact;

(l) removing the portion of the layer of the sacrificial metal under the removed portion of the photoresist;

(m) removing the balance of the photoresist layer, and removing the portion of the first dielectric material under the removed portion of the sacrificial metal layer until reaching at least one of the metal contacts and optionally reaching the space filled by the second dielectric material thus forming at least one via through the sacrificial metal layer and through the additional layer of the first dielectric material.

### BRIEF DESCRIPTION OF THE DRAWINGS

FIG. 1A shows a conventional prior art integrated circuit architecture I.

FIG. 1B shows a second conventional prior art integrated circuit architecture II.

FIG. 1C shows a third conventional prior art integrated circuit architecture III.

FIG. 2A shows an ideal architecture wherein the dielectric immediately above the top of metal lines, Level A, is different from the dielectric below Level A.

FIG. 2B shows a realistic architecture wherein Dielectric I is kept below Level B to ensure that no Dielectric I on top of metal lines.

FIG. 2C shows a first embodiment of a new integrated circuit architecture I according to the invention.

FIG. 2D shows a second embodiment of a new integrated circuit architecture II according to the invention.

FIG. 2E shows a third embodiment of a new integrated circuit architecture III according to the invention.

FIG. 2F shows a fourth embodiment of a new integrated circuit architecture IV according to the invention.

FIG. 3A shows the result of the first step of the formation process for a first embodiment of the invention, architecture I, resulting after inorganic dielectric deposition and metal patterning.

FIG. 3B shows the formation process resulting after deposition of an inorganic dielectric.

FIG. 3C shows the formation process resulting after inorganic dielectric etchback.

FIG. 3D shows the formation process resulting after organic dielectric deposition, inorganic dielectric deposition, and resist application.

FIG. 3E shows the formation process resulting after resist patterning and development.

FIG. 3F shows the formation process resulting after inorganic dielectric etch.

FIG. 3G shows the formation process resulting after organic dielectric etching.

FIG. 4A shows a formation process step for a second embodiment of the invention, architecture II resulting after organic dielectric deposition, metal patterning.

FIG. 4B shows the formation process resulting after deposition of an organic dielectric.

FIG. 4C shows the formation process resulting after organic dielectric etchback.

FIG. 4D shows the formation process resulting after inorganic dielectric deposition, additional organic layer deposition, additional inorganic layer deposition and resist application.

FIG. 4E shows the formation process resulting after resist patterning and development.

FIG. 4F shows the formation process resulting after inorganic dielectric etch.

FIG. 4G shows the formation process resulting after organic dielectric etch.

FIG. 4H shows the formation process resulting after inorganic dielectric etching.

FIG. 5A shows a formation process step for a third embodiment of the invention, architecture III resulting after organic dielectric deposition, metal patterning, inorganic dielectric deposition and etchback, organic dielectric deposition, sacrificial metal layer deposition and resist deposition.

FIG. 5B shows the formation process resulting after resist patterning and development.

FIG. 5C shows the formation process resulting after sacrificial metal etch.

FIG. 5D shows the formation process resulting after organic layer etch.

FIG. 5E shows the formation process resulting after barrier metal and tungsten depositions.

FIG. 5F shows the formation process resulting after removal of the barrier metal, sacrificial metal layer and excess tungsten removal.

FIG. 6A shows a formation process step for a fourth embodiment of the invention, architecture IV resulting after inorganic dielectric deposition, metal patterning, organic dielectric deposition and etchback, inorganic dielectric deposition, sacrificial metal later deposition and resist deposition.

FIG. 6B shows the formation process resulting after resist patterning and development.

FIG. 6C shows the formation process resulting after sacrificial metal etch.

FIG. 6D shows the formation process resulting after resist removal.

FIG. 6E shows the formation process resulting after inorganic layer etch.

FIG. 6F shows the formation process resulting after barrier metal and tungsten depositions.

FIG. 6G shows the formation process resulting after removal of the barrier metal, sacrificial metal layer and excess tungsten removal.

### DETAILED DESCRIPTION OF THE PREFERRED EMBODIMENT

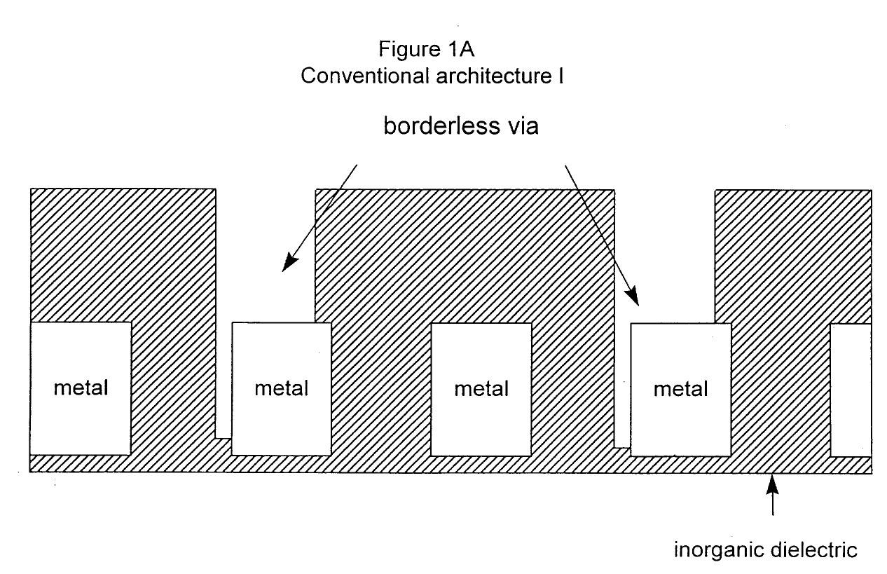

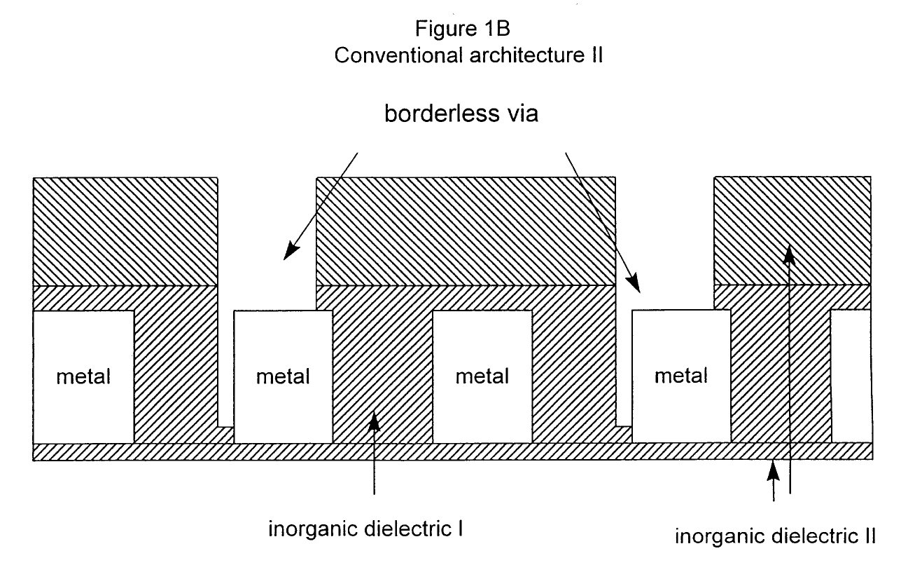

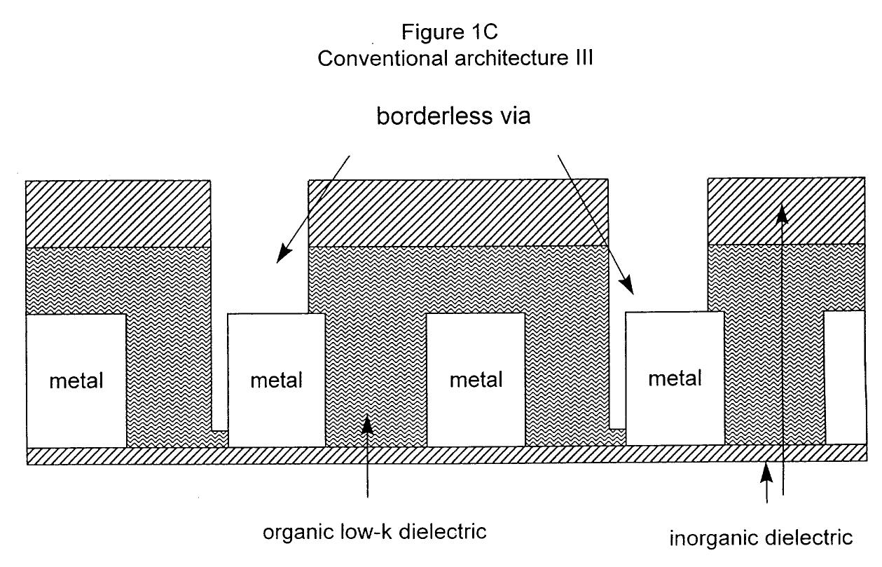

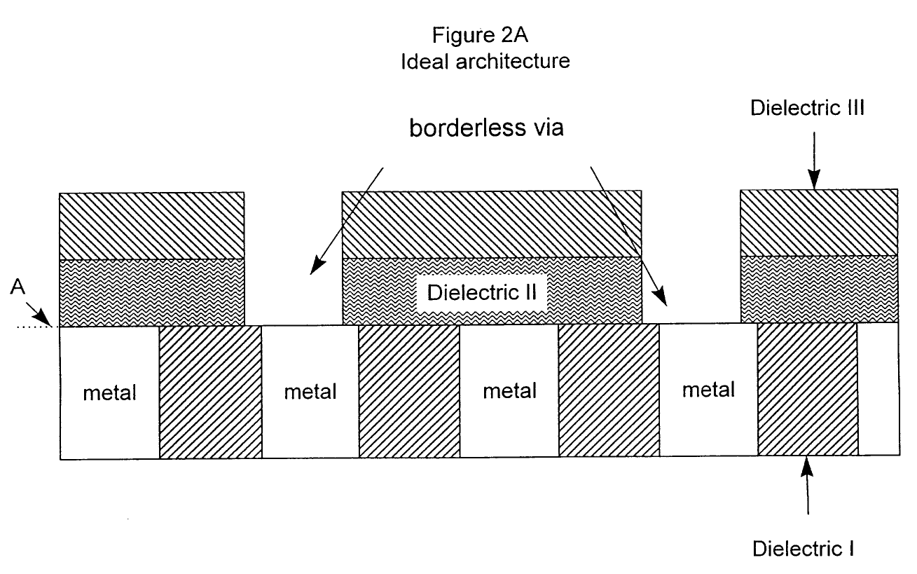

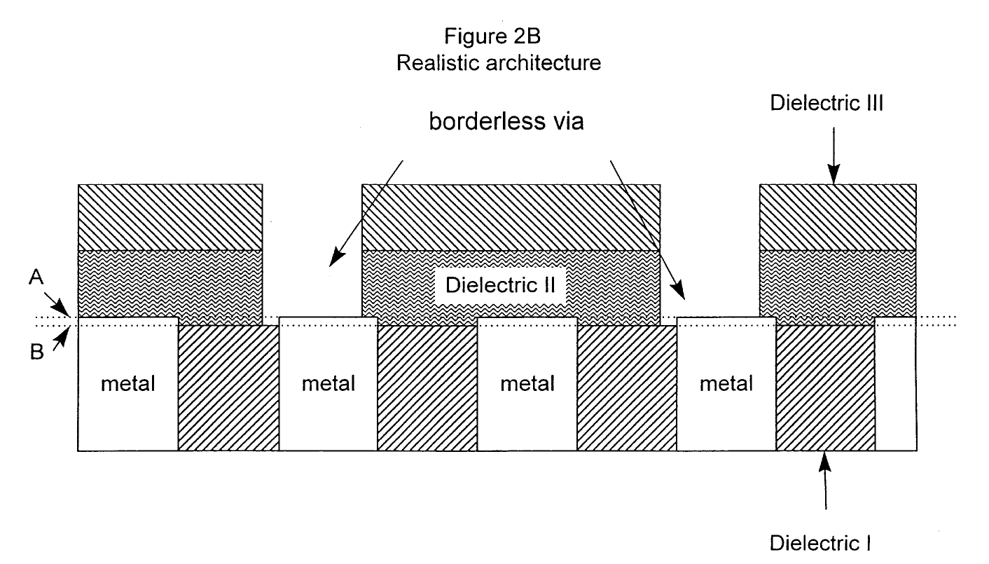

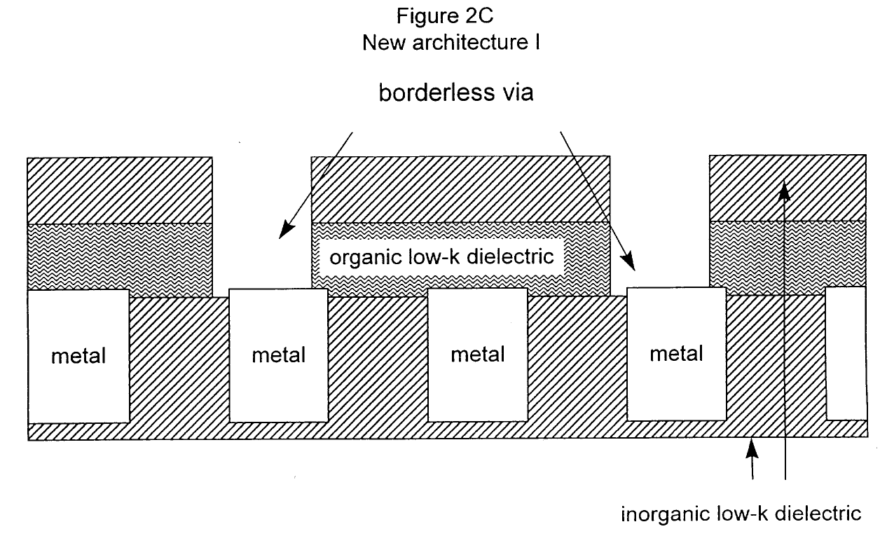

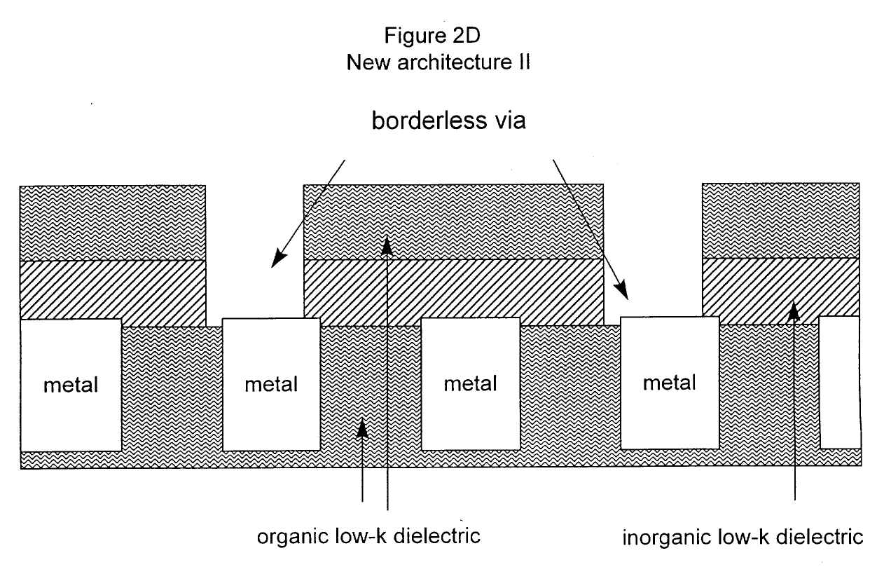

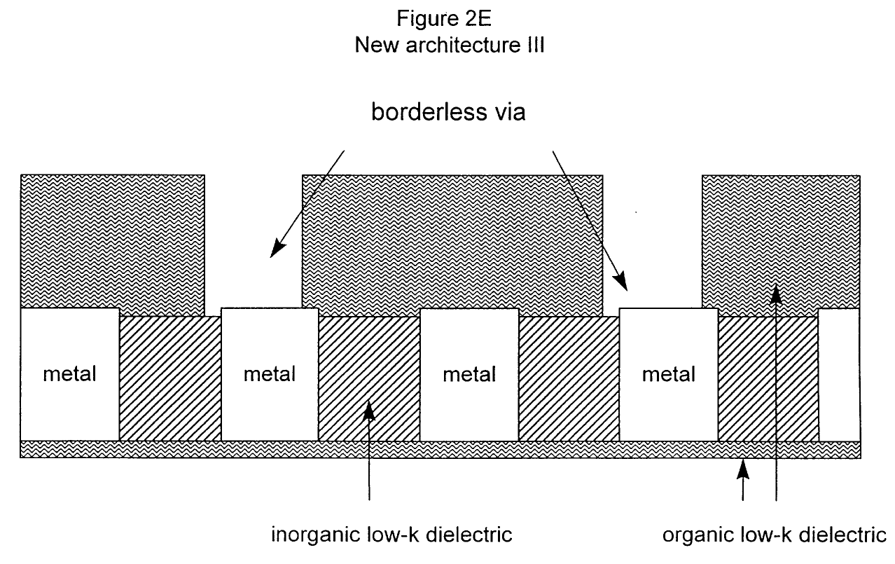

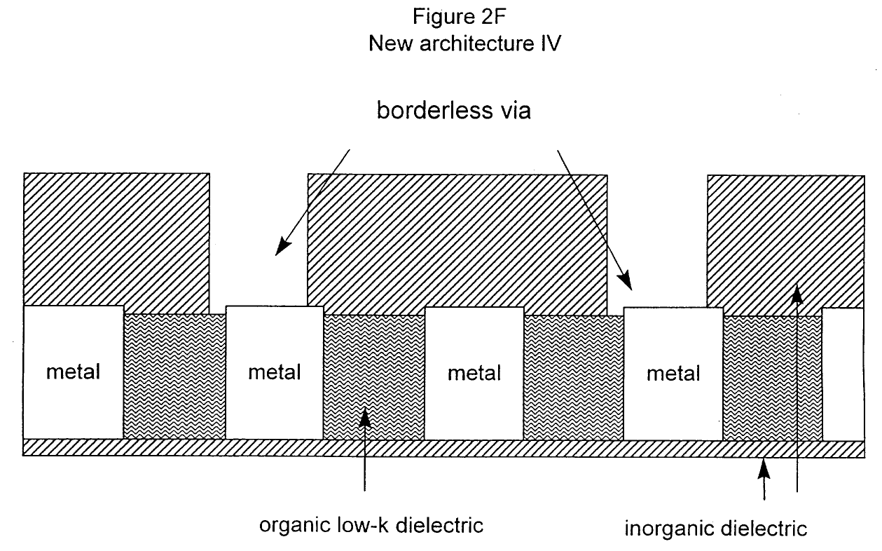

FIGS. 1A-C show prior art integrated circuit conventional architectures I, II and III, and illustrate the problem of producing borderless vias. As can be seen, deep and narrow trenches are typically produced at the side of metal lines in via etching whenever vias are misaligned to the underlying metal lines. According to the present invention, four new architecture embodiments are illustrated in FIGS. 2C through 2F.

The first integrated circuit architecture I according to the invention is show in FIG. 2C. This embodiment uses two different kinds of dielectrics, one inorganic and the other organic for the metal-level and the via-level IMD's, respectively. It comprises a base substrate (not shown) and a layer of a first dielectric material (Dielectric I) on the substrate. A plurality of spaced apart metal contacts are on the layer of the first dielectric material. There is a space between adjacent metal contacts and each space is filled with the first dielectric material. A recess is formed in the filled spaces of the first dielectric material extending from a level at a top of the metal contacts a part of the distance toward the substrate. Then a second dielectric layer (Dielectric II) is formed on at least some of the metal contacts and in the recesses on the filled spaces of the first dielectric material such that there is optionally a gap in the recesses of the second dielectric layer at side walls of the metal contacts. Then an additional layer of the first dielectric material is formed on the second dielectric layer. Thereafter vias are formed through the additional layer of the first dielectric layer and the second dielectric layer extending to the top of at least some of the metal contacts and optionally to the gaps. It is important that the first dielectric material and the second dielectric material have substantially different etch resistance properties. For example, when the first dielectric material is organic then the second dielectric material is inorganic and when the first dielectric material is inorganic then the second dielectric material is organic. The advantage of the invention is a significant difference in plasma etch rate between organic and inorganic dielectrics. This is not possible when the same dielectric is employed for both via-level and metal-level dielectrics. In oxygen-based plasmas, organic dielectrics etch tremendously faster than inorganic dielectrics. Inversely, in carbon fluoride based plasmas, inorganic dielectrics etch much faster than organic dielectrics. In forming a microelectronic device, vias are filled with a metal to form an electrical connection with the metal contacts. Although this application refers to at least one via, in actuality, there are many vias and all are open to extend down to their underlying metal contacts. The purpose of each via is to extend to the underlying metal contacts, however, the via may touch the ledge on its corresponding contact.

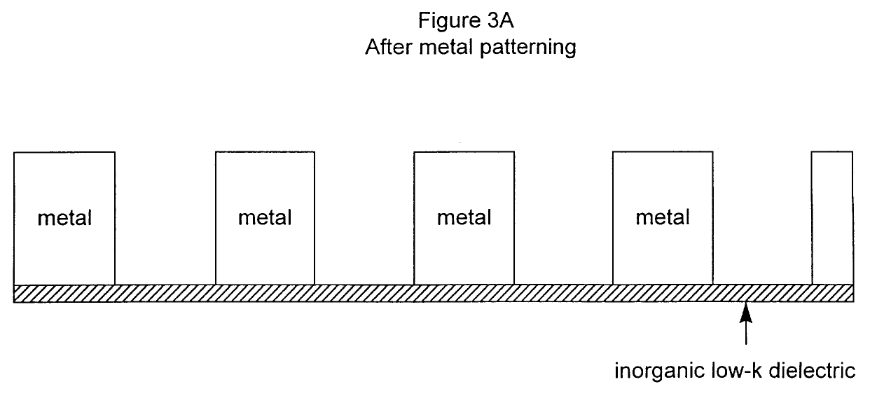

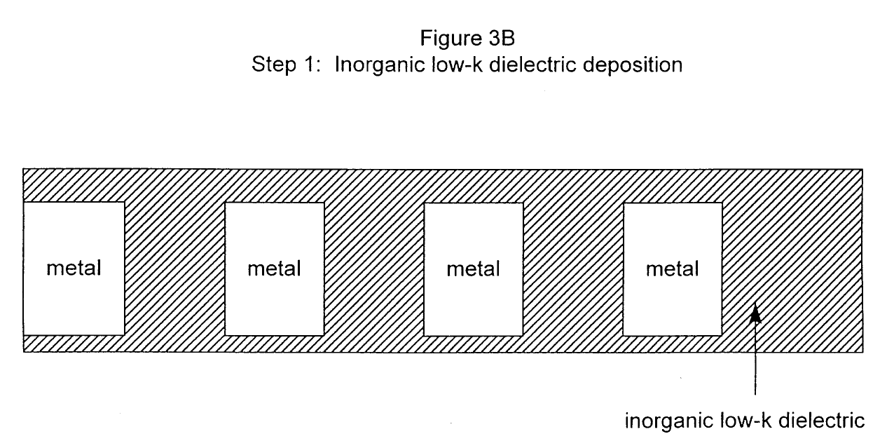

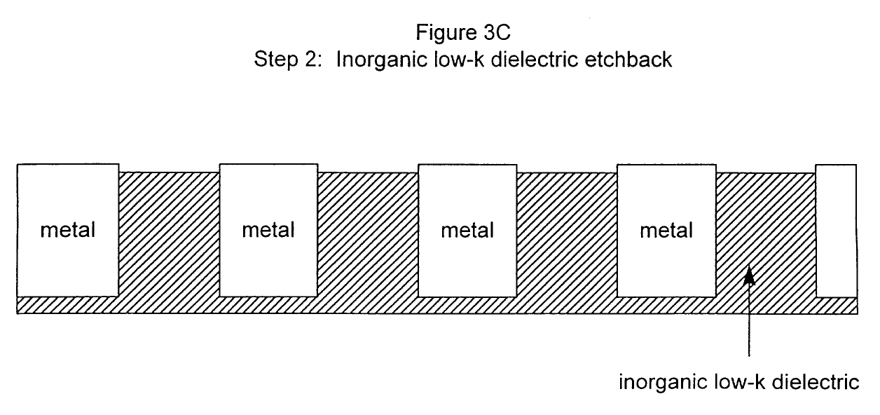

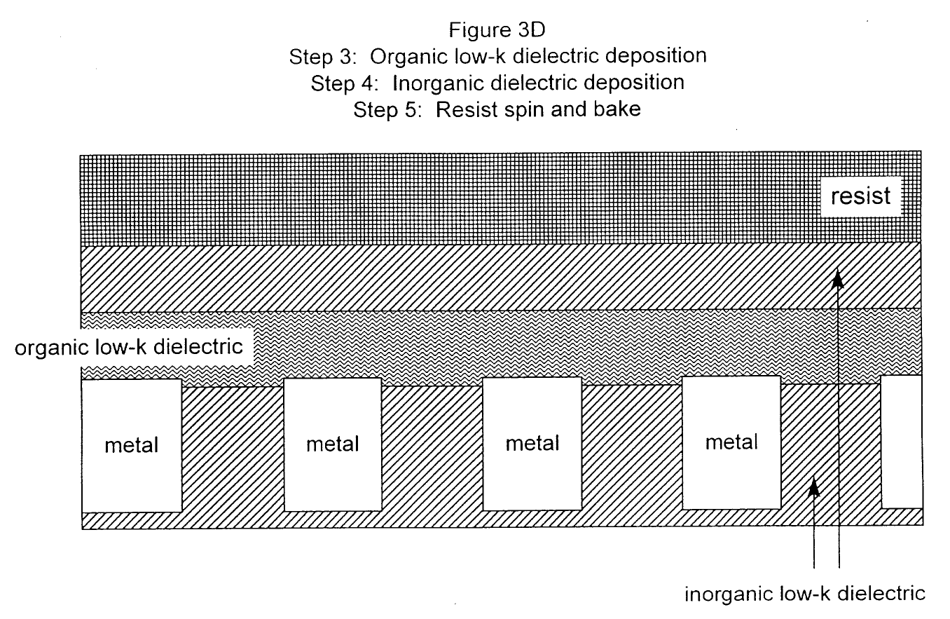

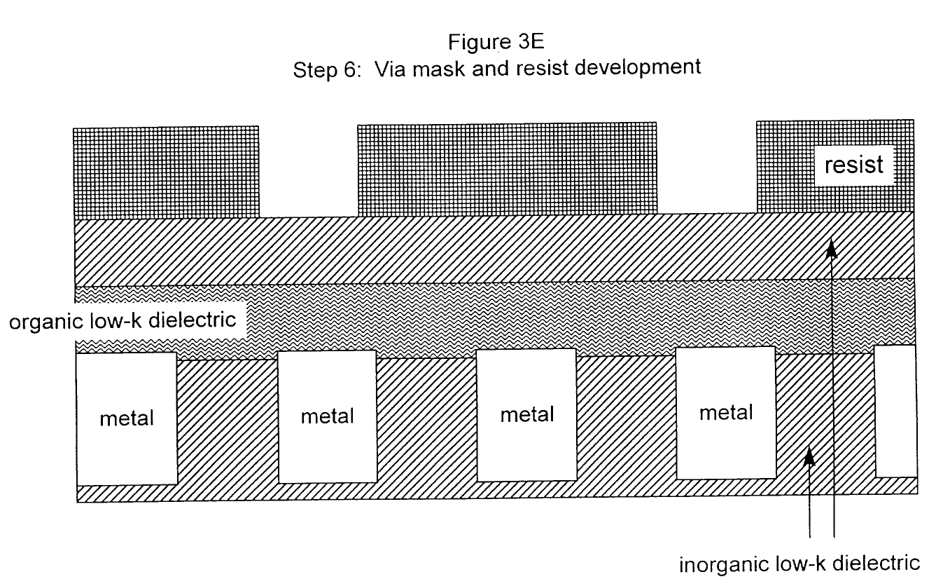

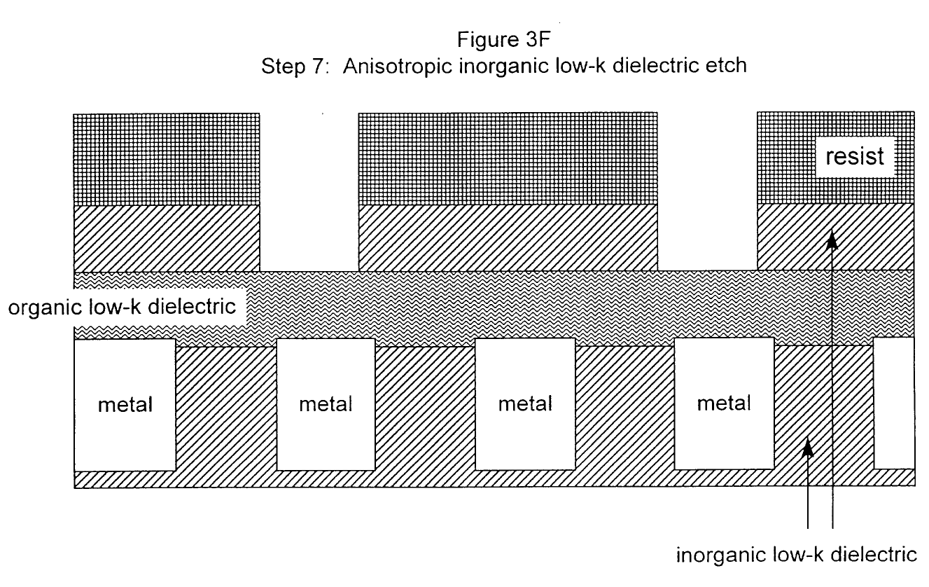

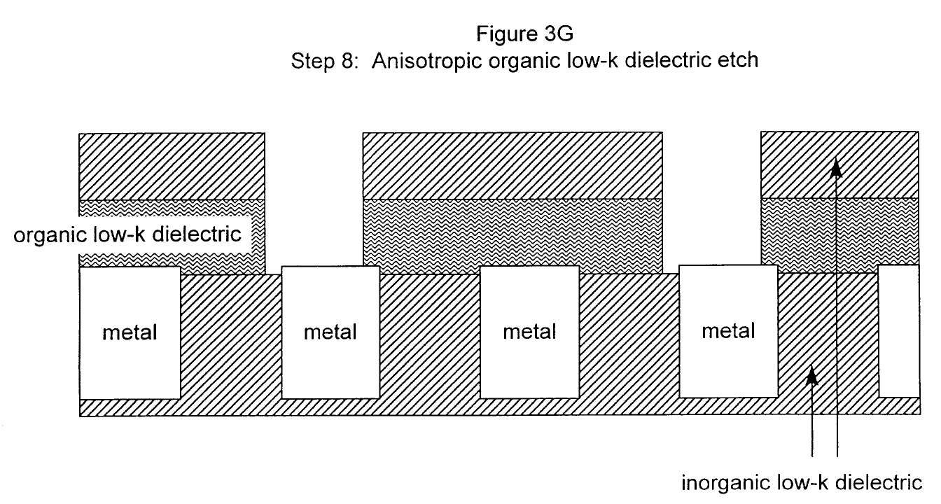

A first process embodiment of the invention for producing new architecture I of FIG. 2C is exemplified by FIGS. 3A through 3G. These figures show the process flow after the formation of the one interconnect level, however, the same processing steps can be repeated again for upper levels of vias and interconnects. FIG. 3A shows the interim structure at a beginning step which is a deposition of an inorganic low-k dielectric (Dielectric I) onto a substrate and forming a pattern of metal contacts on the layer of the first dielectric material. Typical substrates include those suitable to be processed into an integrated circuit or other microelectronic device. Suitable substrates for the present invention non-exclusively include semiconductor materials such as gallium arsenide (GaAs), germanium, silicon, silicon germanium, lithium niobate and compositions containing silicon such as crystalline silicon, polysilicon, amorphous silicon, epitaxial silicon, and silicon dioxide (SiO₂) and mixtures thereof and may include metal contact lines which are typically formed by well known lithographic techniques. Suitable materials for the metal contacts include aluminum, aluminum alloys, copper, copper alloys, titanium, tantalum, and tungsten. These lines form the conductors of an integrated circuit. Such are typically closely separated from one another at distances preferably of from about 20 micrometers or less, more preferably from about 1 micrometer or less, and most preferably of from about 0.05 to about 1 micrometer.

The first process step is to deposit a filling of the first dielectric material (Dielectric I) between the side walls of the metal contacts, as well as on a top surface of the metal contacts as shown in FIG. 3B. Organic and inorganic dielectric compositions may comprise any of a wide variety of dielectric forming materials which are well known in the art for use in the formation of microelectronic devices. The dielectrics may nonexclusively include silicon containing spin-on glasses, i.e. silicon containing polymer such as an alkoxysilane polymer, a silsesquioxane polymer, a siloxane polymer; a poly(arylene ether), a fluorinated poly(arylene ether), other polymeric dielectric materials, nanoporous silica or mixtures thereof The only criteria for this invention in the various embodiments hereinafter described is that Dielectric I has significantly different etch resistance properties from Dielectric II. Useful organic dielectrics are those which follow which are carbon containing and inorganics are those which follow which are not carbon containing.

One useful polymeric dielectric material useful for the invention include an nanoporous silica alkoxysilane polymer formed from an alkoxysilane monomer which has the formula:

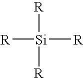

wherein at least 2 of the R groups are independently C₁ to C₄ alkoxy groups and the balance, if any, are independently selected from the group consisting of hydrogen, alkyl, phenyl, halogen, substituted phenyl. Preferably each R is methoxy, ethoxy or propoxy. Such are commercially available from AlliedSignal as Nanoglass™. The most preferred alkoxysilane monomer is tetraethoxysilane (TEOS). Also useful are hydrogensiloxanes which have the formula [(HSiO_{1.5})ₓO_{y}]ₙ. hydrogensilsesquioxanes which have the formula (HSiOl_{1.5})ₙ, and hydroorganosiloxanes which have the formulae [(HSiO_{1.5})ₓO_{y}(RSiO_{1.5})ₙ, [(HSiO_{1.5})ₓ(RSiO_{1.5})_{y}], and [(HSiO_{1.5})ₓO_{y}(RSiO_{1.5})_{z}]ₙ. In each of these polymer formulae, x= about 6 to about 20, y=1 to about 3, z= about 6 to about 20, n=1 to about 4,000, and each R is independently H, C₁ to C₈ alkyl or C₆ to C₁₂ aryl. The weight average molecular weight may range from about 1,000 to about 220,000. In the preferred embodiment n ranges from about 100 to about 800 yielding a molecular weight of from about 5,000 to about 45,000. More preferably, n ranges from about 250 to about 650 yielding a molecular weight of from about 14,000 to about 36,000. Useful polymers within the context of this invention nonexclusively include hydrogensiloxane, hydrogensilsesquioxane, hydrogenmethylsiloxane, hydrogenethylsiloxane, hydrogenpropylsiloxane, hydrogenbutylsiloxane, hydrogentert-butylsiloxane, hydrogenphenylsiloxane, hydrogenmethylsilsesquioxane, hydrogenethylsilsesquioxane, hydrogenpropylsilsesquioxane, hydrogenbutylsilsesquioxane, hydrogentert-butylsilsesquioxane and hydrogenphenylsilsesquioxane and mixtures thereof Useful organic polymers include polyimides, fluorinated and nonfluorinated polymers, in particular fluorinated and nonfluorinated poly(arylethers) available under the tradename FLARE™ from AlliedSignal Inc., and copolymer mixtures thereof. The hydroorganosiloxanes, poly(arylene ethers), fluorinated poly(arylene ethers) and mixtures thereof are preferred. Suitable poly(arylene ethers) or fluorinated poly(arylene ethers) are known in the art from U.S. Pat. Nos. 5,155,175; 5,114,780 and 5,115,082. Preferred poly(arylene ethers) and fluorinated poly(arylene ethers) are disclosed in U.S. patent application Ser. No. 08/990,157 filed Dec. 12, 1997 which is incorporated herein by reference. Preferred siloxane materials suitable for use in this invention are commercially available from AlliedSignal Inc. under the tradename Accuglass® T-11, T-12 and T-14. Also usefil are methylated siloxane polymers available from AlliedSignal Inc. under the tradenames Purespin™ and Accuspin® T18, T23 and T24.

Preferred silicon containing dielectric resins include polymers having a formula selected from the group consisting of [(HSiO_{1.5})ₓO_{y}]ₙ,(HSiO_{1.5})ₙ, [(HSiO_{1.5})ₓO_{y}(RSiO_{1.5})_{z}]ₙ, [(HSiO_{1.5})ₓ(RSiO_{1.5})_{y}]ₙ and [(HSiO_{1.5})ₓO_{y}(RSiO_{1.5})_{z}]ₙ wherein x= about 6 to about 20, y=1 to about 3, z= about 6 to about 20, n=1 to about 4,000, and each R is independently H, C₁ to C₈ alkyl or C₆ to C₁₂ aryl which are disclosed in U.S. patent application Ser. No. 08/955,802 filed Oct. 22, 1997 and which is incorporated herein by reference. Also preferred are certain low organic content silicon containing polymers such as those having the formula I:

[H—SiO_{1.5}]ₙ[R—SiO_{1.5}]ₘ,

[H_{0.4-1.0}SiO_{1.5-1.8}]ₙ[R_{0.4-1.0}—SiO_{1.5-1.8}]ₘ,

[H_{0-0.1}—SiO_{1.5-2.0}]ₙ[R—SiO_{1.5}]ₘ,

[H—SiO_{1.5}]ₓ[R—SiO_{1.5}]_{y}[SiO₂]_{z},

wherein the sum of n and m, or the sum or x, y and z is from about 8 to about 5000, and m and y are selected such that carbon containing substituents are present in an amount of less than about 40 Mole percent. Polymers having the structure I are of low organic content where the carbon containing substituents are present in an amount of less than about 40 mole percent. These polymers are described more fully in U.S. patent application Ser. No. 09/044,831, filed Mar. 20, 1998, which is incorporated herein by reference. Also preferred are certain high organic content silicon containing polymers such as those having the formula II:

[HSiO_{1.5}]ₙ[RSiO_{1.5}]ₘ,

[H_{0.4-1.0}SiO_{1.5-1.8}]ₙ[R_{0.4-1.0}SiO_{1.5-1.8}]ₘ,

[H_{0-0.1}—SiO_{1.5-2.0}]ₙ[RSiO_{1.5}]ₘ,

wherein the sum of n and m is from about 8 to about 5000 and m is selected such that the carbon containing substituent is present in an amount of from about 40 Mole percent or greater; and

[HSiO_{1.5}]ₓ[RSiO_{1.5}]_{y}[SiO₂]_{z};

wherein the sum of x, y and z is from about 8 to about 5000 and y is selected such that the carbon containing substituent is present in an amount of about 40 Mole % or greater; and wherein R is selected from substituted and unsubstituted straight chain and branched alkyl groups, cycloalkyl groups, substituted and unsubstituted aryl groups, and mixtures thereof The specific mole percent of carbon containing substituents is a function of the ratio of the amounts of starting materials. Polymers having the structure II which are of high organic content where the carbon containing substituents are present in an amount of about 40 mole percent or more. These polymers are described more fully in U.S. patent application Ser. No. 09/044,798, filed Mar. 20, 1998, which is incorporated herein by reference.

The polymer may be present in the dielectric composition in a pure or neat state (not mixed with any solvents) or it may be present in a solution where it is mixed with solvents. When solvents are present, the polymer is preferably present in an amount of from about 1% to about 50% by weight of the polymer, more preferably from about 3% to about 20%. The solvent component is preferably present in an amount of from about 50% to about 99% by weight of the dielectric composition, more preferably from about 80% to about 97%. Suitable solvents nonexclusively include aprotic solvents such as cyclic ketones including cyclopentanone, cyclohexanone, cyclohexanone and cyclooctanone; cyclic amides such as N-alkylpyrroldinone wherein the alkyl group has from 1 to about 4 carbon atoms, and N-cyclohexyl-pyrrolidinone, and mixtures thereof

Deposition of the dielectric onto the substrate may be conducted via conventional spin-coating, dip coating, roller coating, spraying, chemical vapor deposition methods, or meniscus coating methods which are well-known in the art. Spin coating is most preferred. The thickness of the dielectric layers may vary depending on the deposition procedure and parameter setup, but typically the thickness may range from about 500 Å to about 50,000 Å, and preferably from about 2000 Å to about 12000 Å. In the preferred embodiment, a liquid dielectric composition is spun onto the appropriate surface according to known spin techniques such as by applying a liquid dielectric composition to the surface and then spinning on a rotating wheel at speeds ranging from about 500 to about 6000 rpm for about 5 to about 60 seconds. The layer preferably has a density of from about 1 g/cm³ to about 3 g/cm³.

The dielectric on the metal contacts may be conformally deposited using chemical vapor deposition techniques. The as-deposited thickness of the dielectric is required to be such that its thickness on the sidewall of metal lines is no less than the allowable misalignment between the subsequently printed via and the metal lines underneath it. On the other hand, the dielectric needs be kept thin enough so that no keyholes are formed in it.

The dielectrics may optionally be heated to expel residual solvent or to increase its molecular weight. The heating may be conducted by conventional means such as heating on a hot plate in air or in an inert atmosphere, or it may occur in a furnace or oven in air, or in an inert atmosphere, or it may occur in a vacuum furnace or vacuum oven. Heating is preferably conducted at a temperature of from about 80° C. to about 500° C., and more preferably from about 150° C. to about 425° C. This heating is preferably performed from about 1 minute to about 360 minutes, and more preferably from about 2 to about 60 minutes. The dielectric layer may also optionally be exposed to actinic light, such as UV light, to increase its molecular weight. The amount of exposure may range from about 100 MJ/cm² to about 300 mJ/cm². The dielectric layers may optionally be cured by overall exposed to electron beam radiation. Electron beam exposure may be controlled by setting the beam acceleration. Electron beam radiation may take place in any chamber having a means for providing electron beam radiation to substrates placed therein. It is preferred that the electron beam exposing step is conducted with a wide, large beam of electron radiation from a large area electron beam source. Preferably, an electron beam chamber is used which provides a large area electron source. Suitable electron beam chambers are commercially available from Electron Vision, a unit of AlliedSignal Inc., under the trade name “ElectronCure™”. The principles of operation and performance characteristics of such device are described in U.S. Pat. No. 5,003,178, the disclosure of which is incorporated herein by reference. The temperature of the electron beam exposure preferably ranges from about 20° C. to about 450° C., more preferably from about 50° C. to about 400° C. and most preferably from about 200° C. to about 400° C. The electron beam energy is preferably from about 0.5 KeV to about 30 KeV, and more preferably from about 3 to about 10 KeV. The dose of electrons is preferably from about 1 to about 50,000 μC/cm² and more preferably from about 50 to about 20,000 PC/cm². The gas ambient in the electron beam tool can be any of the following gases: nitrogen, oxygen, hydrogen, argon, a blend of hydrogen and nitrogen, ammonia, xenon or any combination of these gases. The electron beam current is preferably from about 1 to about 40 mA, and more preferably from about 5 to about 20 mA. Preferably, the electron beam exposing step is conducted with a wide, large beam of electron beam radiation from a uniform large-are electron beam source which covers an area of from about 4 inches to about 256 square inches.

The next step 2 is removing the first dielectric material from the top surface of the metal contacts and forming a recess in the space between adjacent side walls of the metal contacts as shown in FIG. 3C. This is done by etchback. The etchback needs to be well-controlled to minimize the recess produced by it. The etchback can be performed in fluorine-based plasma chemistry. In step 3 one then deposits a layer of a second dielectric material (Dielectric II) in the recess and on the top surface of the metal contacts.

In step 4 one deposits an additional layer of the first dielectric material on the top second dielectric. In step 5 a layer of a photoresist is then applied and baked on the layer of the additional layer of the first dielectric to produce the structure of FIG. 3D. The photoresist composition may be positive working or negative working and are generally commercially available. Suitable positive working photoresists are well known in the art and may comprise an o-quinone diazide radiation sensitizer. The o-quinone diazide sensitizers include the o-quinone-4-or-5-sulfonyl-diazides disclosed in U.S. Pat. Nos. 2,797,213; 3,106,465; 3,148,983; 3,130,047; 3,201,329; 3,785,825; and 3,802,885. When o-quinone diazides are used, preferred binding resins include a water insoluble, aqueous alkaline soluble or swellable binding resin, which is preferably a novolak. Suitable positive photoresists may be obtained commercially, for example, under the trade name of AZ-P4620 from Clariant Corporation of Somerville, N.J. After imagewise removing a portion of the photoresist over at least one metal contact and optionally over at least a portion of the first dielectric layer between the metal contacts in step 6, the structure of FIG. 3E is attained. Such is performed in a manner well known in the art such as by imagewise exposing the photoresist to actinic radiation such as through a suitable mask and developing the photoresist. The photoresist may be imagewise exposed to actinic radiation such as light in the visible, ultraviolet or infrared regions of the spectrum through a mask, or scanned by an electron beam, ion or neutron beam or X-ray radiation. Actinic radiation may be in the form of incoherent light or coherent light, for example, light from a laser. The photoresist is then imagewise developed using a suitable solvent, such as an aqueous alkaline solution. Optionally the photoresist is heated to cure the image portions thereof and thereafter developed to remove the nonimage portions and define a via mask. After removing the portion of the additional layer of the first dielectric under the removed portion of the photoresist in a step 7, the structure of FIG. 3F is obtained. This is done by etching. The etch, preferably done in fluorine-based plasma chemistry, stops by itself on reaching the underlying second dielectric due to a significantly high etch selectivity between the first and second dielectrics. In step 10, one performs an anisotropic organic dielectric etch. The etch of the exposed organic dielectric, in oxygen-based plasma chemistry, stops by itself on reaching on the metal and the inorganic dielectric due to a very high etch selectivity between organic dielectric and metal and between organic and inorganic dielectrics. At the completion of this step, via holes are fully opened without deep and narrow trenches produced on the side of metal lines. The resist, being organic, is simultaneously removed and the structure of FIG. 3G is obtained. One then deposits a layer of a barrier metal on the additional layer of first dielectric, and on inside walls and a floor of the vias and fills the vias with a fill metal and deposits a layer of a fill metal on the layer of the barrier metal. A barrier metal serves to prevent diffusion of the conductive metal into the dielectric layers. The barrier metal may be, for example, Ti or a nitride such TaN or TiN. A barrier metal which is a bilayered film of titanium and TiN can be used. Then the top of the barrier metal layer is covered with a fill metal. At the same time the vias are filled with the fill metal. Suitable fill metals include aluminum, aluminum alloys, copper, copper alloys, tantalum, tungsten, titanium or other metals or mixtures thereof as typically employed in the formation of microelectronic devices. The metals may be applied by such techniques as vapor deposition, sputtering, evaporation and the like. Copper is most preferred. As used herein, the term “a metal” includes amalgams of metals. One then removes the fill metal layer and the barrier metal layer. The process steps used for the fabrication of the via and metal levels can be repeated again for the upper levels of vias and metals.

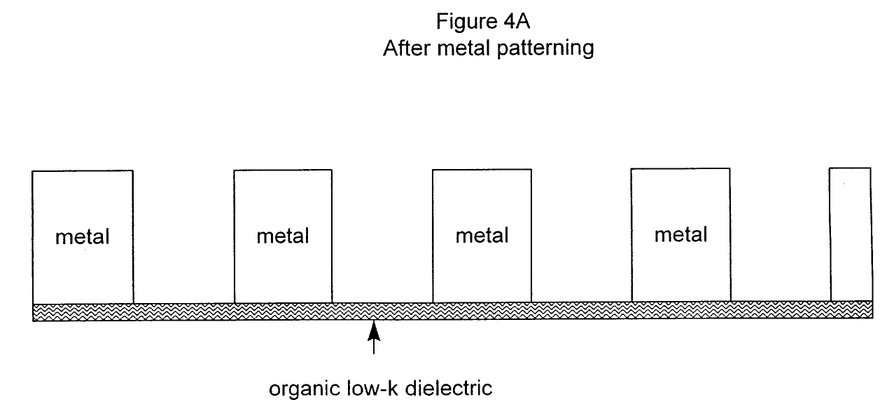

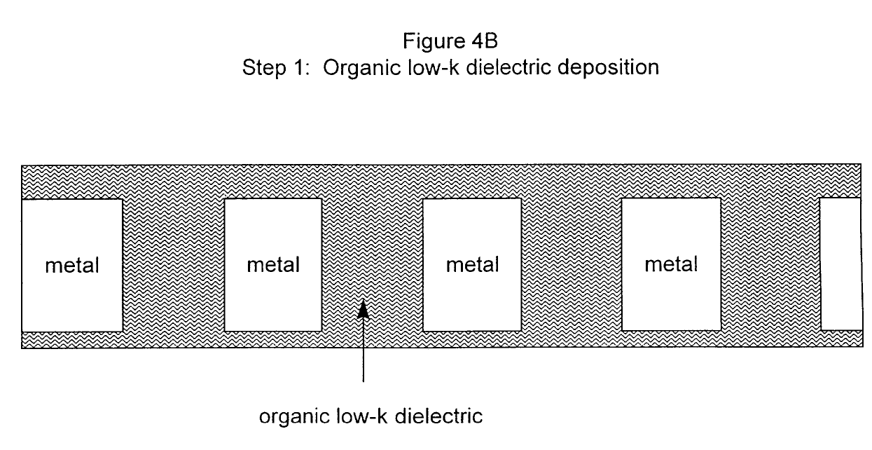

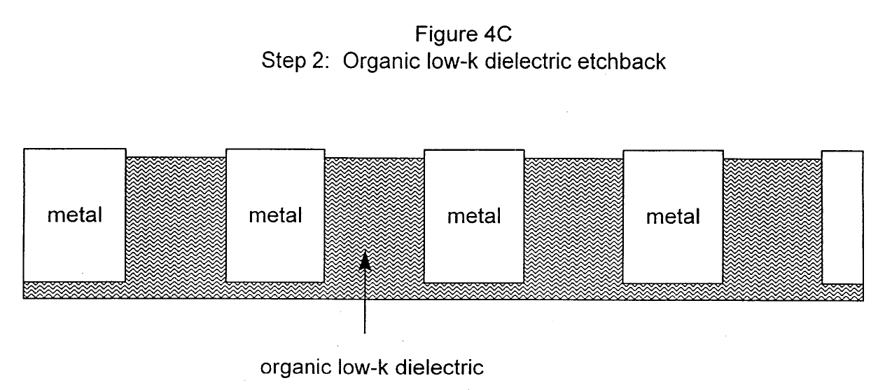

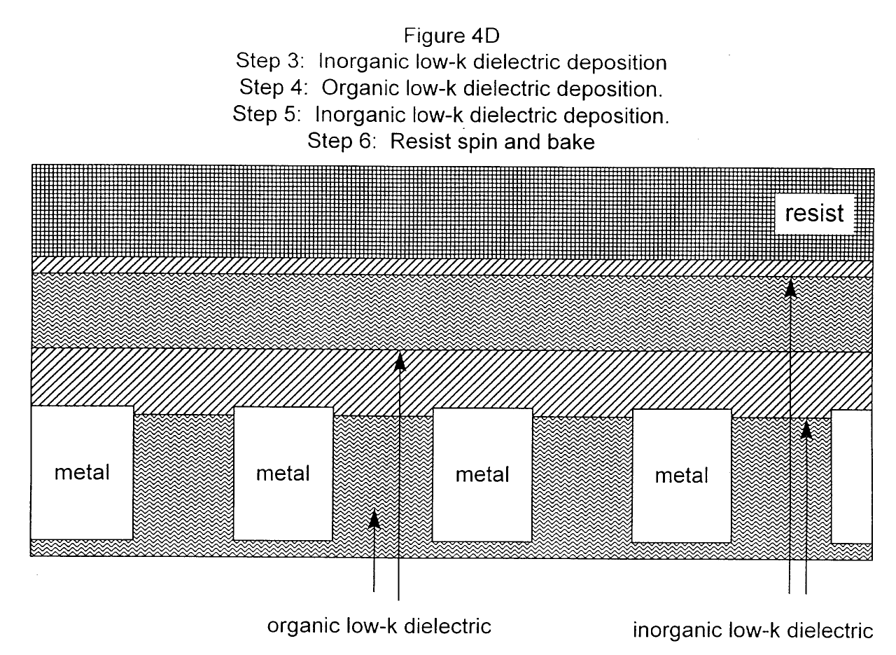

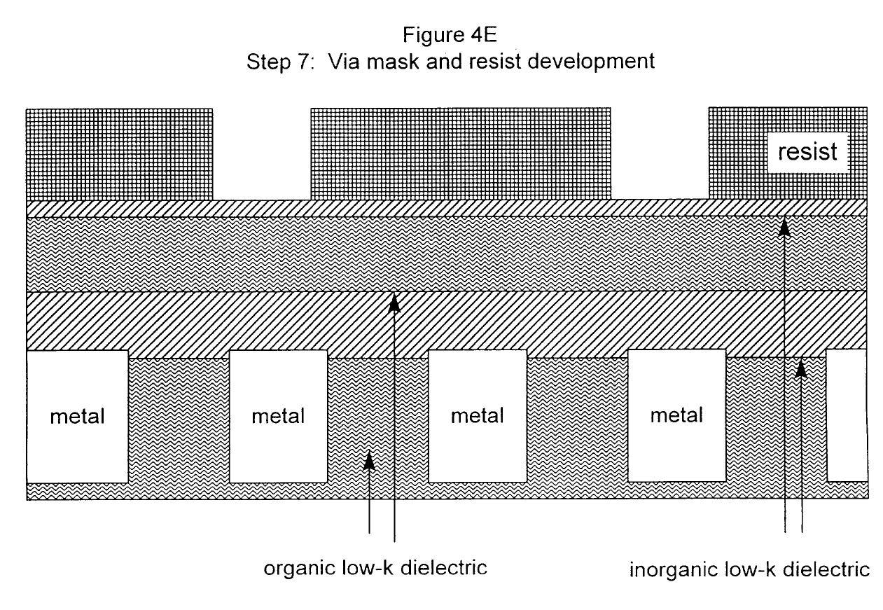

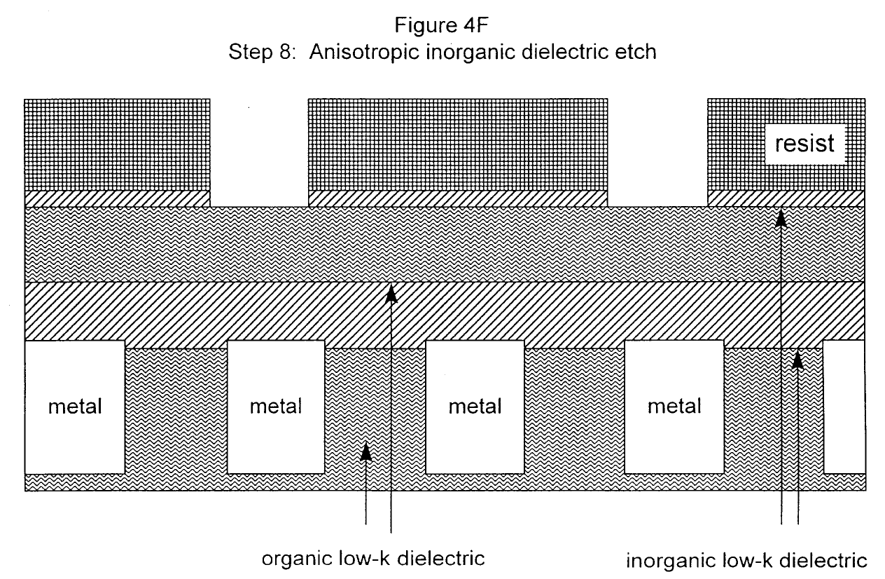

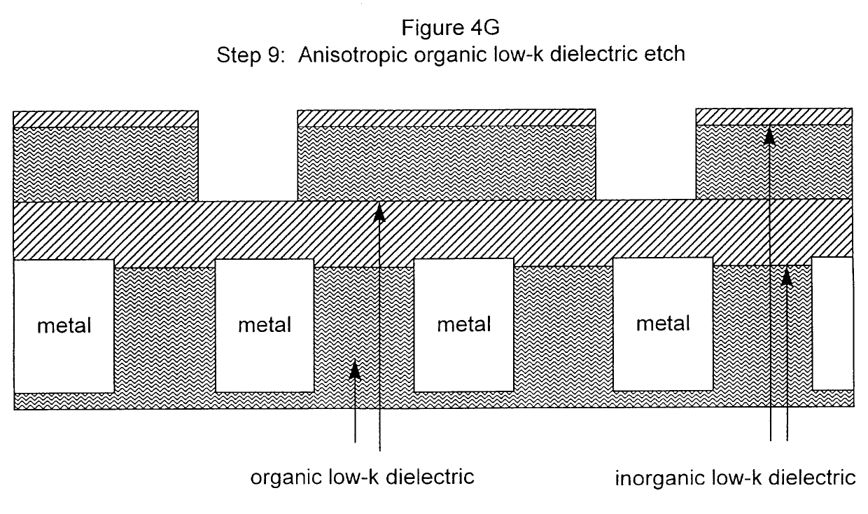

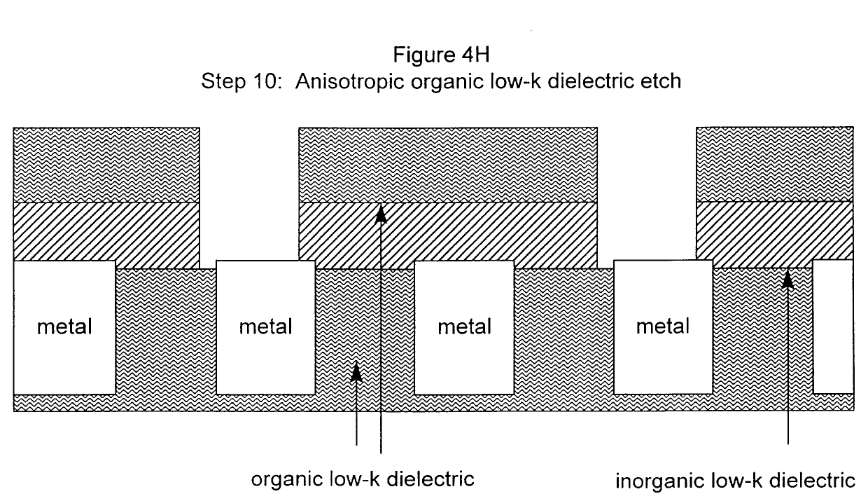

A second embodiment of the invention produces new architecture II as shown in FIG. 2D. The structure and process steps are analogous to those for architecture I except the organic and inorganic dielectrics are reversed. FIG. 4A shows a formation process step for a second embodiment of the invention, architecture II resulting after organic dielectric deposition and metal patterning. FIG. 4B shows the formation process resulting after step 1, which is deposition of an organic dielectric. The next step 2 is removing the first organic dielectric material from the top surface of the metal contacts and forming a recess in the space between adjacent side walls of the metal contacts as shown in FIG. 4C by etchback. In step 3 one then deposits a layer of a second inorganic dielectric material (Dielectric II) in the recess and on the top surface of the metal contacts. In step 4 one deposits an additional layer of the first organic dielectric material on top of the inorganic second dielectric. In step 5 one deposits an additional layer of the first inorganic dielectric material on top of the additional layer of the organic second dielectric. In step 6 a layer of a photoresist is then applied and baked on the layer of the additional layer of the first dielectric to produce the structure of FIG. 4D.

After imagewise removing a portion of the photoresist over at least one metal contact and optionally over at least a portion of the first dielectric layer between the metal contacts in step 7, the structure of FIG. 4E is attained. After removing the portion of the additional layer of the first dielectric under the removed portion of the photoresist in a step 8, the structure of FIG. 4F is obtained. This is done by etching. The etch stops by itself on reaching the additional layer of the first organic dielectric due to a significantly high etch selectivity between the first and second dielectrics. In step 9, one performs an anisotropic organic dielectric etch. The etch of the exposed organic dielectric, in oxygen-based plasma chemistry, stops by itself on reaching the inorganic dielectric due to a very high etch selectivity between organic and inorganic dielectrics as seen in FIG. 4G. In step 10, one performs an inorganic dielectric etch. The etch of the exposed inorganic dielectric, stops by itself on reaching the metal contacts or organic dielectric due to a very high etch selectivity between organic and inorganic dielectrics and inorganic dielectric and metal contact as seen in FIG. 4H. At the completion of this step, via holes are fully opened without deep and narrow trenches produced on the side of metal lines.

A third embodiment of the invention produces new architecture III as shown in FIG. 2E. The structure has a substrate, a layer of a first dielectric material on the substrate and a spaced apart metal contacts on the layer of the first dielectric material. There is a space between adjacent metal contacts filled with a second dielectric material. The layer of the second dielectric has a recess in the filled spaces which extend from a level at a top of the metal contacts a part of the distance toward the substrate. An additional layer of the first dielectric layer is on at least some of the metal contacts and in the recesses on the filled spaces of the second dielectric material such that there is optionally a gap in the recesses of the first dielectric layer at side walls of the metal contacts. Vias are formed through the additional layer of the first dielectric layer extending to the top of at least some of the metal contacts and optionally to the gaps. Again, first dielectric material and the second dielectric material must have substantially different etch resistance properties. In this third embodiment, the first dielectric is organic and the second dielectric is inorganic.

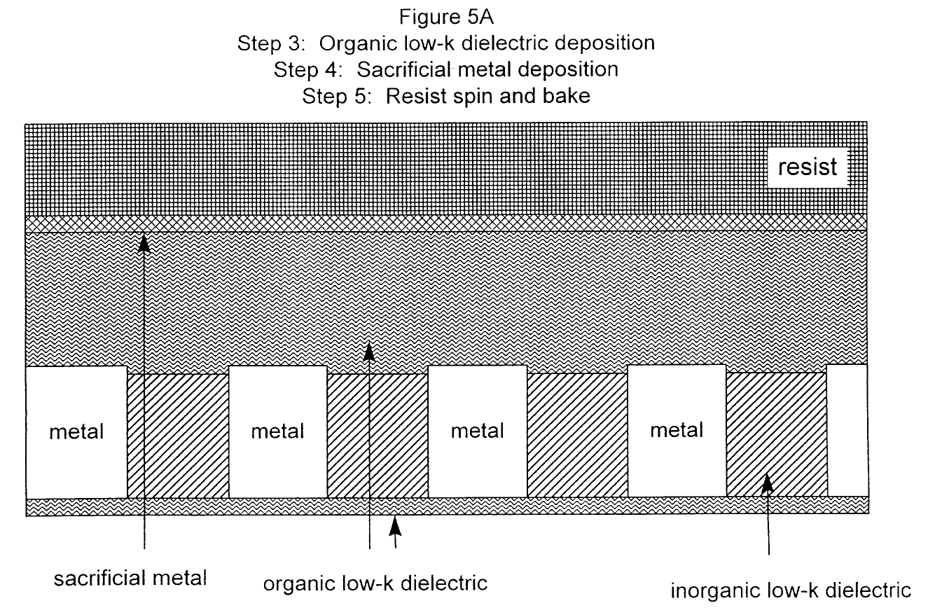

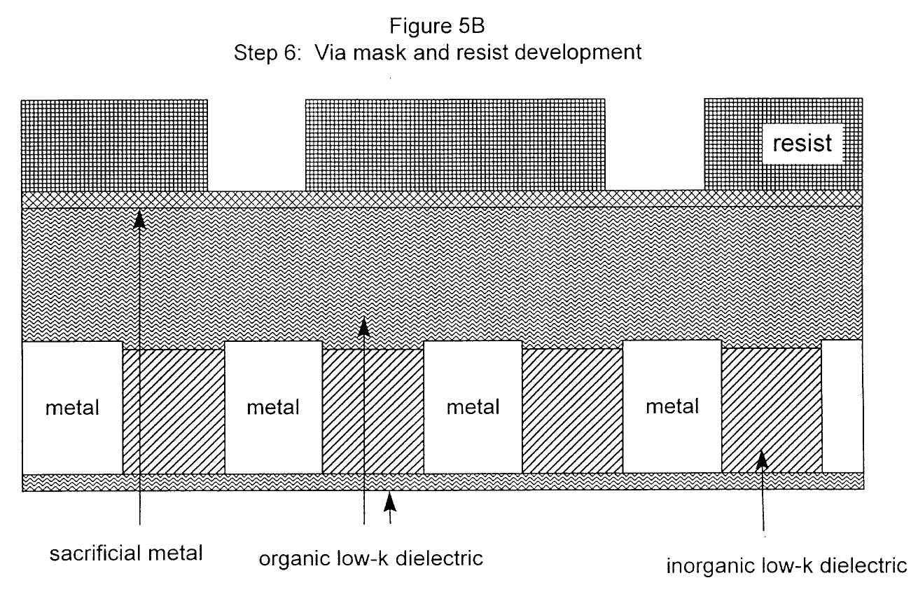

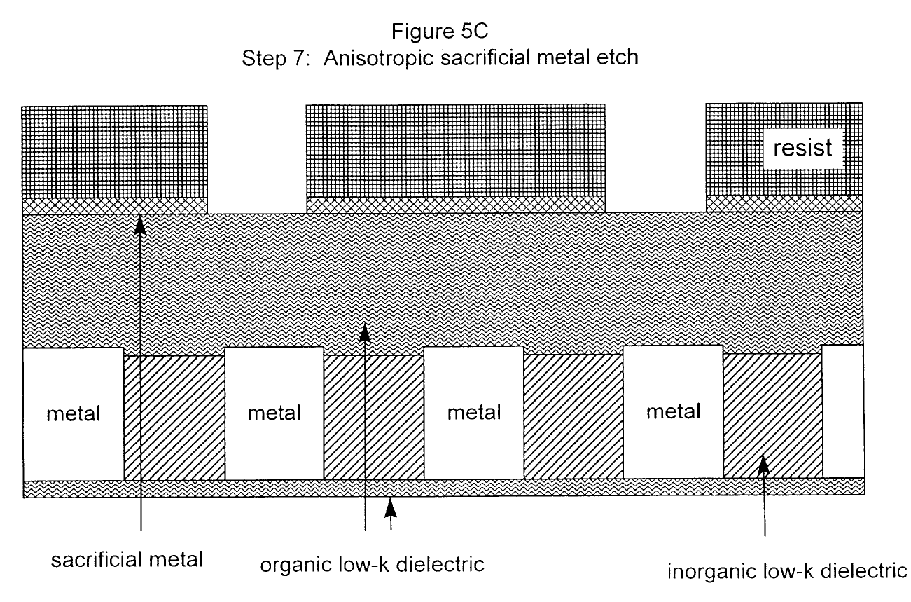

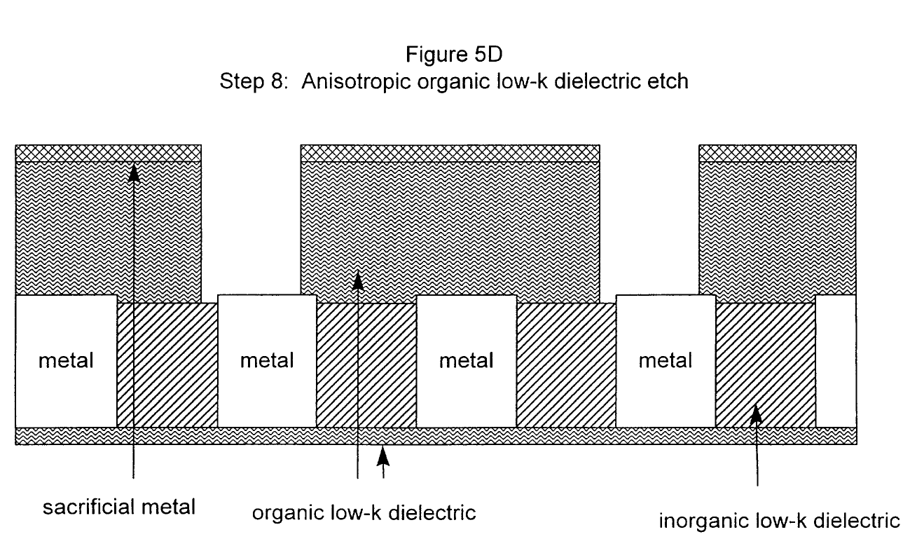

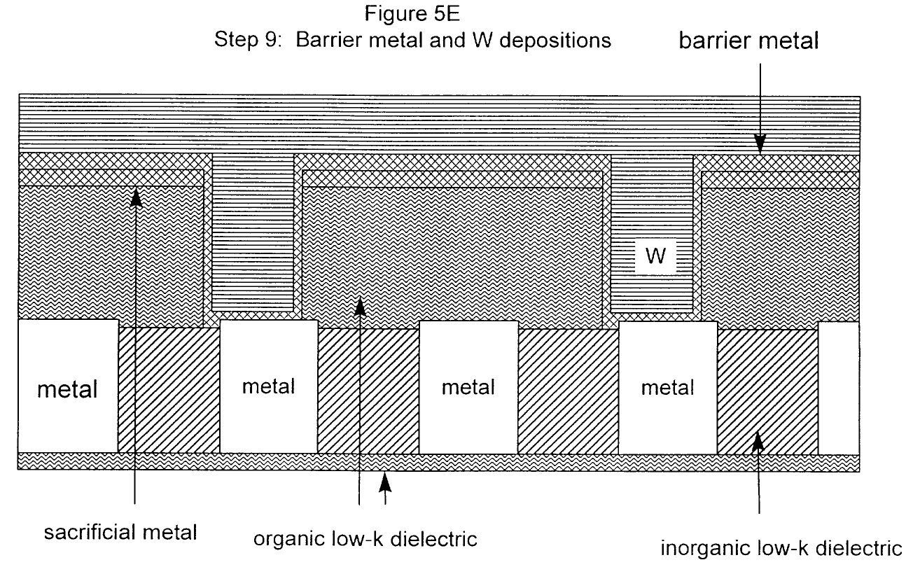

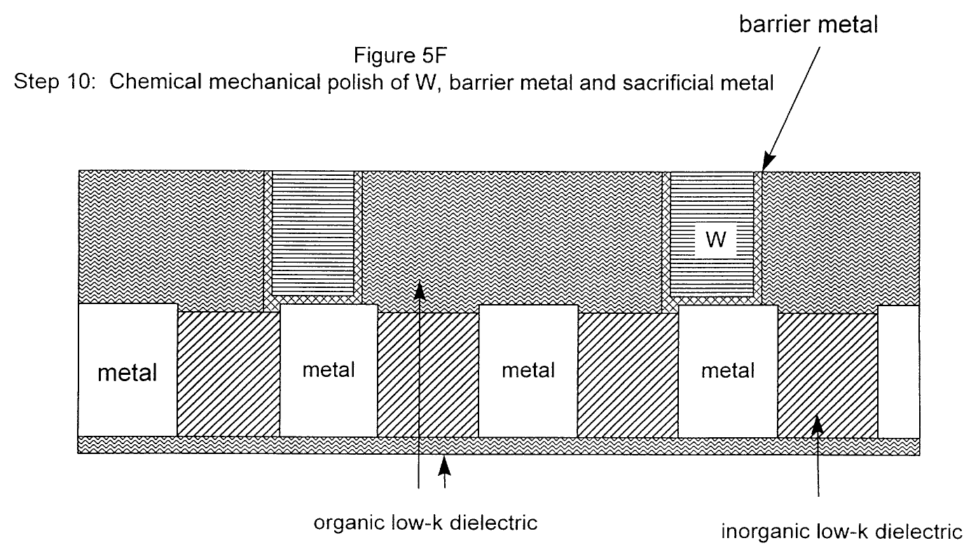

A process sequence for the production of the structure of FIG. 2E is shown via FIGS. 5A through 5D. These figures show the process flow after the formation of the one interconnect level, however, the same processing steps can be repeated again for upper levels of vias and interconnects.

FIG. 5A shows the interim structure after step 1 which is deposition of a first organic dielectric onto a substrate, forming a pattern of metal contacts on the layer of first organic dielectric and forming a layer of a second inorganic dielectric on and between the metal contacts. The structure and process steps are analogous to those above. Typical materials for the substrates and metal contacts have been described above. The next step 2 is removing the second inorganic dielectric material from the top surface of the metal contacts and forming a recess in the space between adjacent side walls of the metal contacts by etchback. In step 3 one then deposits an additional layer of the first organic dielectric material in the recess and on the top surface of the metal contacts. In step 4 one deposits a layer of sacrificial metal on the additional layer of first organic dielectric material. The layer of a sacrificial metal separates the underlying organic dielectric previously deposited from the resist to be spun in the next step. Significantly high etch selectivity can be easily achieved between inorganic dielectrics and metal thin film and between organic dielectrics and metal thin films. The sacrificial metal protects the underlying organic dielectric when resist is removed after the completion of opening via. Any suitable etchable metal may be used for this layer such as titanium nitride or tungsten. In step 5 one deposits a layer of a photoresist on the layer of the sacrificial metal layer to thereby produce the structure of FIG. 5A. After imagewise removing a portion of the photoresist over at least one metal contact and optionally over at least a portion of the first dielectric layer between the metal contacts in step 6, the structure of FIG. 5B is attained. After removing the portion of the layer of the sacrificial metal under the removed portion of the photoresist in a step 7, the structure of FIG. 5C is obtained. This is done by anisotropic sacrificial metal etch. The etch, preferably done in chlorine-based plasma chemistry, and stops by itself on reaching the underlying dielectric due to a significantly high etch selectivity between metal and the dielectric. In step 8, one performs an anisotropic organic dielectric etch. The etch of the exposed organic dielectric, in oxygen-based plasma chemistry, stops by itself on reaching on the metal and the inorganic dielectric due to a very high etch selectivity between organic dielectric and metal and between organic and inorganic dielectrics. At the completion of this step, via holes are fully opened without deep and narrow trenches produced on the side of metal lines. Furthermore, the sacrificial metal has become redundant and is to be removed later.

The resist, being organic, is simultaneously removed and the structure of FIG. 5D is obtained. One then deposits a layer of a barrier metal on the sacrificial metal layer, and on inside walls and a floor of the vias and fills the vias with a fill metal and deposits a layer of a fill metal on the layer of the barrier metal in a step 9 to produce the structure of FIG. 5E. A barrier metal serves to prevent diffuision of the conductive metal into the dielectric layers. The barrier metal may be, for example, Ti or a nitride such TaN or TiN. A barrier metal which is a bilayered film of titanium and TiN can be used. Then the top of the barrier metal layer is covered with a fill metal. At the same time the vias are filled with the fill metal. Suitable fill metals include aluminum, aluminum alloys, copper, copper alloys, tantalum, tungsten, titanium or other metals or mixtures thereof as typically employed in the formation of microelectronic devices. The metals may be applied by such techniques as vapor deposition, sputtering, evaporation and the like. Copper is most preferred. As used herein, the term “a metal” includes amalgams of metals. One then removes the fill metal layer, the barrier metal layer and the sacrificial metal layer for example by chemical mechanical polishing to produce the structure of FIG. 5F. The process steps used for the fabrication of the via and metal levels can be repeated again for the upper levels of vias and metals.

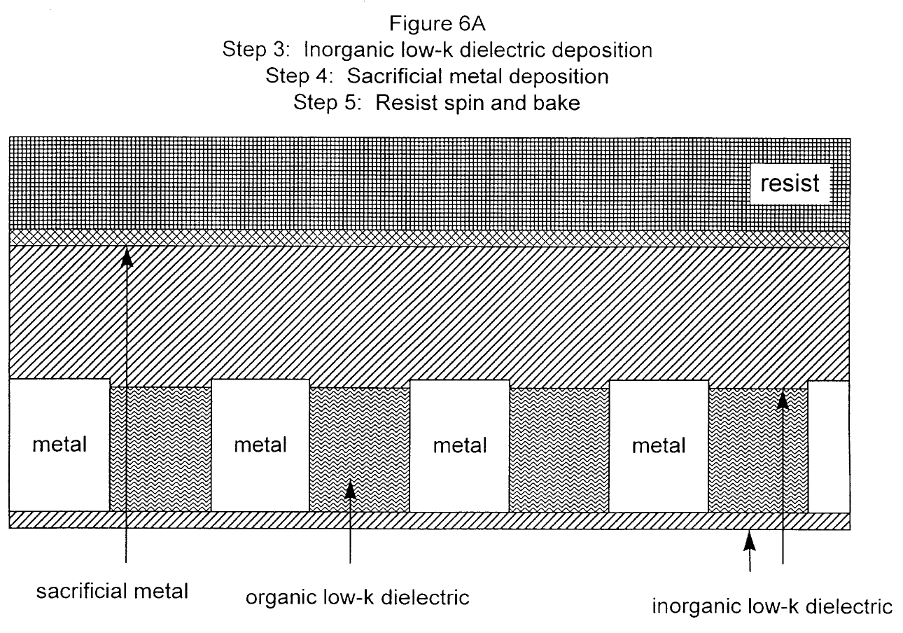

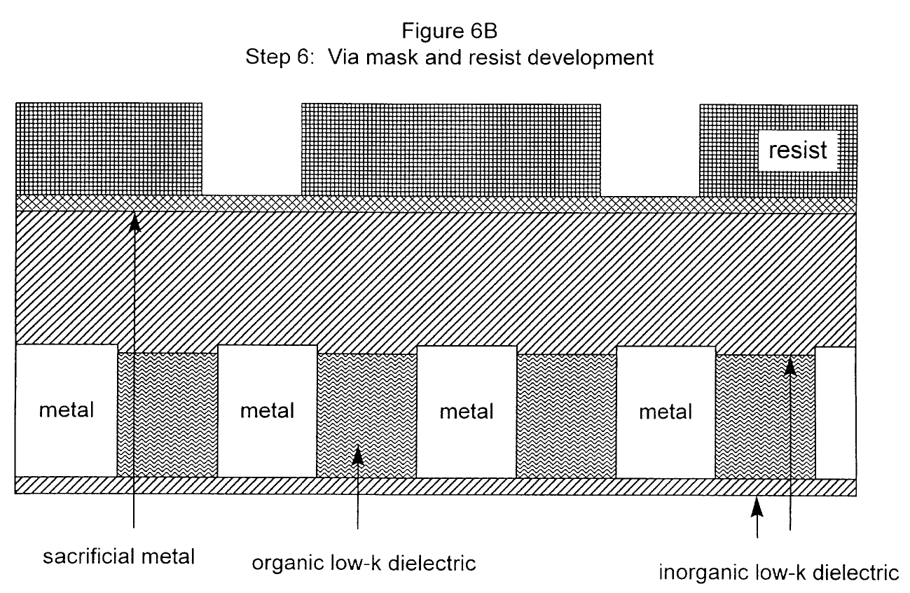

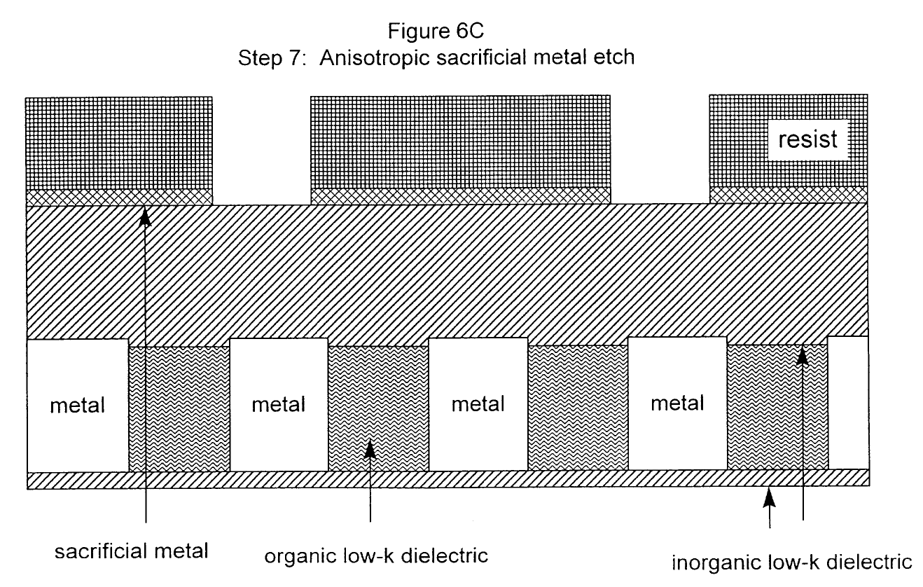

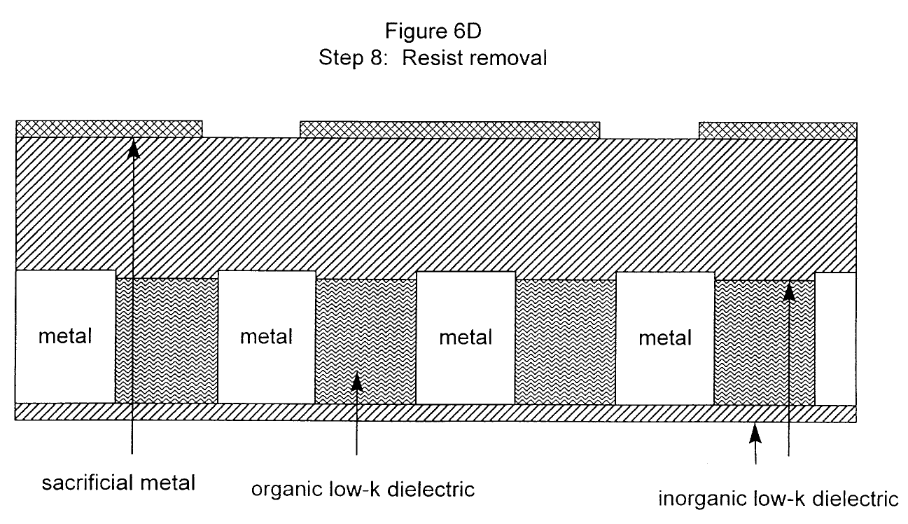

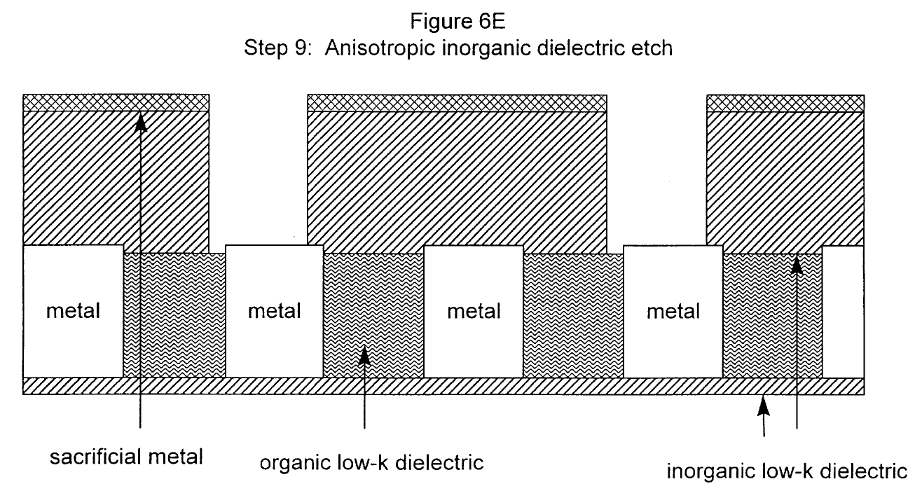

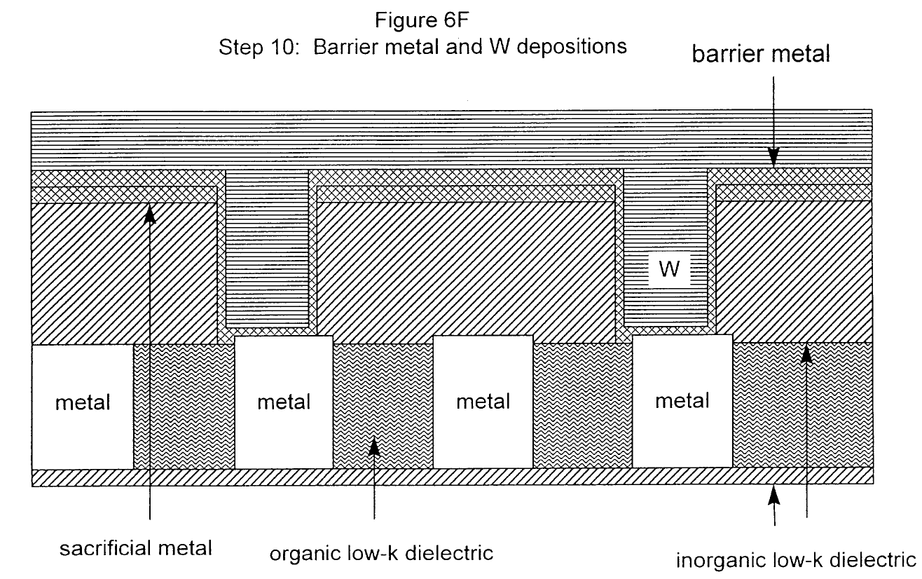

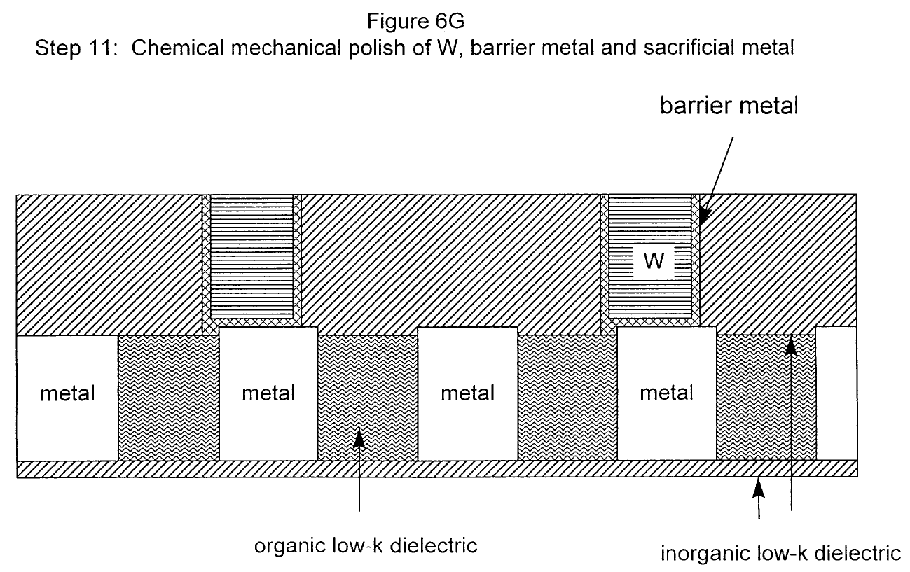

The process steps for preparing the structure of new architecture IV is similar to those for producing new architecture III except the organic and inorganic dielectrics are reversed. A process sequence for the fourth embodiment of the invention for producing new architecture IV of FIG. 2F is exemplified by FIGS. 6A through 6G. These figures show the process flow after the formation of the one interconnect level, however, the same processing steps can be repeated again for upper levels of vias and interconnects.

FIG. 6A shows the interim structure after step I which is deposition of a first inorganic dielectric onto a substrate, forming a pattern of metal contacts on the layer of first inorganic dielectric and forming a layer of a second organic dielectric on and between the metal contacts. The structure and process steps are analogous to those above. Typical materials for the substrates and metal contacts have been described above. The next step 2 is removing the second organic dielectric material from the top surface of the metal contacts and forming a recess in the space between adjacent side walls of the metal contacts by etchback. In step 3 one then deposits an additional layer of the first inorganic dielectric material in the recess and on the top surface of the metal contacts. In step 4 one deposits a layer of sacrificial metal on the additional layer of first inorganic dielectric material. The layer of a sacrificial metal separates the underlying inorganic dielectric previously deposited from the resist to be spun in the next step. Significantly high etch selectivity can be easily achieved between inorganic dielectrics and metal thin films. The sacrificial metal protects the underlying inorganic dielectric when the resist is removed after the completion of via opening. In step 5 one deposits a layer of a photoresist on the layer of the sacrificial metal layer to thereby produce the structure of FIG. 6A. After imagewise removing a portion of the photoresist over at least one metal contact and optionally over at least a portion of the second dielectric layer between the metal contacts in step 6, the structure of FIG. 6B is attained. After removing the portion of the layer of the sacrificial metal under the removed portion of the photoresist in a step 7, the structure of FIG. 6C is obtained. This is done by anisotropic sacrificial metal etch. The etch stops by itself on reaching the underlying dielectric due to a significantly high etch selectivity between metal and the dielectric. In step 8, one removes the resist to obtain the structure of FIG. 6D. In Step 9 one etches the exposed inorganic dielectric. The etch stops by itself on reaching on the metal and the organic dielectric due to a very high etch selectivity between inorganic dielectric and metal and between organic and inorganic dielectrics. At the completion of this step, via holes are fully opened without deep and narrow trenches produced on the side of metal lines. Furthermore, the sacrificial metal has become redundant and is to be removed later. The structure of FIG. 6E is obtained. One then deposits a layer of a barrier metal on the sacrificial metal layer, and on inside walls and a floor of the vias and fills the vias with a fill metal and deposits a layer of a fill metal on the layer of the barrier metal in a step 10 to produce the structure of FIG. 6F. A barrier metal serves to prevent diffusion of the conductive metal into the dielectric layers. The barrier metal may be those mentioned above. Then the top of the barrier metal layer is covered with a fill metal and at the same time the vias are filled with the fill metal. Suitable fill metals include those mentioned above. One then removes the fill metal layer, the barrier metal layer and the sacrificial metal layer for example by chemical mechanical polishing to produce the structure of FIG. 6G. The process steps used for the fabrication of the via and metal levels can be repeated again for the upper levels of vias and metals.

While the present invention has been particularly shown and described with reference to preferred embodiments, it will be readily appreciated by those of ordinary skill in the art that various changes and modifications may be made without departing from the spirit and scope of the invention. It is intended that the claims be to interpreted to cover the disclosed embodiment, those alternatives which have been discussed above and all equivalents thereto.

What is claimed is:

1. An integrated circuit structure which comprises
(a) a substrate;
(b) a layer of a first dielectric material on the substrate;
(c) a plurality of spaced apart metal contacts on the layer of the first dielectric material;
(d) a space between adjacent metal contacts, each space being filled with the first dielectric material;
(e) a recess in the filled spaces of the first dielectric material extending from a level at a top of the metal contacts a part of the distance toward the substrate;
(f) a second dielectric layer on at least some of the metal contacts and in the recesses on the filled spaces of the first dielectric material such that there is optionally a gap in at least one of the recesses of the second dielectric layer at a side wall of a metal contact;
(g) an additional layer of the first dielectric material on the second dielectric layer;
(h) at least one via extending through the additional layer of the first dielectric layer and the second dielectric layer extending to the top of at least one of the metal contacts and optionally to a gap;
wherein the first dielectric material and the second dielectric material have substantially different etch resistance properties.

2. The integrated circuit structure of claim 1 wherein the via is filled with at least one metal.

3. The structure of claim 1 wherein the first dielectric material is organic and the second dielectric material is inorganic.

4. The structure of claim 1 wherein the first dielectric material is inorganic and the second dielectric material is organic.

5. An integrated circuit structure which comprises
(a) a substrate;
(b) a layer of a first dielectric material on the substrate;
(c) a plurality of spaced apart metal contacts on the layer of the first dielectric material;
(d) a space between adjacent metal contacts, each space being filled with a second dielectric material;
(e) a recess in the filled spaces of the second dielectric material extending from a level at a top of the metal contacts a part of the distance toward the substrate;
(f) an additional layer of the first dielectric layer on at least some of the metal contacts and in the recesses on the filled spaces of the second dielectric material such that there is optionally a gap in at least one the recesses of the first dielectric layer at a side wall of a metal contact;
(g) at least one via extending through the additional layer of the first dielectric layer extending to the top of at least one of the metal contacts and optionally to a gaps;
wherein the first dielectric material and the second dielectric material have substantially different etch resistance properties.

6. The integrated circuit structure of claim 5 wherein the via is filled with at least one metal.

7. The structure of claim 5 wherein the first dielectric material is organic and the second dielectric material is inorganic.

8. The structure of claim 5 wherein the first dielectric material is inorganic and the second dielectric material is organic.

9. A process for producing an integrated circuit structure which comprises
(a) providing a substrate;
(b) depositing a layer of a first dielectric material onto the substrate;
(c) forming a pattern of metal contacts on the layer of the first dielectric material including a space between adjacent metal contacts;
(d) depositing a layer of the first dielectric material on a top surface of the metal contacts and filling in the space between the metal contacts with the first dielectric material;
(e) removing the first dielectric material from the top surface of the metal contacts and removing an upper portion of the first dielectric material from the filled space between the metal contacts to form a recess;
(f) depositing a layer of a second dielectric material on the metal contacts and filling the recess with second dielectric material, wherein the first dielectric material and the second dielectric material have substantially different etch resistance properties;
(g) depositing an additional layer of the first dielectric material over the layer of the second dielectric material;
(h) depositing a layer of a photoresist on the additional layer of the first dielectric material;
(i) imagewise removing a portion of the photoresist over some of the metal contacts and optionally over a portion of at least one of the filled recesses adjacent to a side wall of a metal contact;
(j) removing the portion of the layer of the additional layer of the first dielectric material under the removed portion of the photoresist;
(k) removing the balance of the photoresist layer, and removing the portion of the second dielectric material under the removed portion of the additional layer of the first dielectric material until reaching at least one of the metal contacts and optionally reaching the space filled by the first dielectric material thus forming at least one via through the additional layer of the first dielectric material and through the layer of the second dielectric material.

10. The process of claim 9 further comprising:
(n) depositing a layer of a barrier metal on the additional layer of the first dielectric material, and on inside walls and a floor of the at least one via;
(o) filling the at least one via with a fill metal and depositing a layer of a fill metal on the layer of the barrier metal;
(p) removing the fill metal layer, the barrier metal layer and optionally the additional layer of the first dielectric material.

11. The process of claim 9 wherein the first dielectric material is organic and the second dielectric material is inorganic.

12. The process of claim 9 wherein the first dielectric material is inorganic and the second dielectric material is organic.

13. A process for producing an integrated circuit structure which comprises
(a) providing a substrate;
(b) depositing a layer of a first dielectric material onto the substrate;
(c) forming a pattern of metal contacts on the layer of the first dielectric material including a space between adjacent metal contacts;
(d) depositing a layer of a second dielectric material on a top surface of the metal contacts and filling in the space between the metal contacts with the second dielectric material;
(e) removing the second dielectric material from the top surface of the metal contacts and removing an upper portion of the second dielectric material from the filled space between the metal contacts to form a recess;
(f) depositing an additional layer of a first dielectric material on the metal contacts and filling the recess with first dielectric material, wherein the first dielectric material and the second dielectric material have substantially different etch resistance properties;
(g) depositing a layer of a sacrificial metal on the additional layer of the first dielectric material;
(h) depositing a layer of a photoresist on the layer of the sacrificial metal layer;
(k) imagewise removing a portion of the photoresist over some of the metal contacts and optionally over a portion of at least one of the filled recesses adjacent to a side wall of a metal contact;
(l) removing the portion of the layer of the sacrificial metal under the removed portion of the photoresist;
(m) removing the balance of the photoresist layer, and removing the portion of the first dielectric material under the removed portion of the sacrificial metal layer until reaching at least one of the metal contacts and optionally reaching the space filled by the second dielectric material thus forming at least one via through the sacrificial metal layer and through the additional layer of the first dielectric material.

14. The process of claim 13 further comprising:
(n) depositing a layer of a barrier metal on the sacrificial metal layer, and on inside walls and a floor of the at least one via;
(o) filling the at least one via with a fill metal and depositing a layer of a fill metal on the layer of the barrier metal;
(p) removing the fill metal layer, the barrier metal layer and the sacrificial metal layer.

15. The process of claim 13 wherein the first dielectric material is organic and the second dielectric material is inorganic.

16. The process of claim 13 wherein the first dielectric material is inorganic and the second dielectric material is organic.
